(19) United States
(12) Patent Application Publication
(10) Pub. No.: US 2022/0246747 A1
(43) Pub. Date: Aug. 4, 2022

(54) Contact Etch Stop Layer with Improved Etch Stop Capability

(71) Applicant: Tokyo Electron Limited, Tokyo (JP)

(72) Inventors: Yun Han, Albany, NY (US); Alok Ranjan, Austin, TX (US); Shihsheng Chang, Albany, NY (US); Andrew Metz, Albany, NY (US); Peter Ventzek, Austin, TX (US)

(21) Appl. No.: 17/167,260

(22) Filed: Feb. 4, 2021

(51) Int. Cl. H01L 29/66; H01L 21/8234; H01L 29/78; H01L 27/088

(52) U.S. Cl. CPC H01L 29/66795; H01L 27/0886; H01L 29/785; H01L 21/823431

(57) ABSTRACT

Improved process flows and methods are provided herein for fabricating a transistor on a substrate. In the disclosed process flows and methods, a contact etch stop layer (CESL) is conformally deposited directly onto a plurality of transistor structures, and a sacrificial layer is conformally deposited directly onto the CESL to protect the CESL from oxidation and thinning during subsequent processing step(s). The sacrificial layer improves the etch stop capability of the CESL during a subsequently performed oxide etch process. By providing a CESL with improved etch stop capability, the disclosed process flows and methods provide a controlled CESL etch process, which reduces or avoids damage to underlying transistor structures.

### BACKGROUND

The present disclosure relates to the processing of substrates. In particular, it provides a novel transistor fabrication process and method that protects a contact etch stop layer (CESL) from oxidation and thinning during subsequent processing steps of the transistor fabrication process. In one embodiment, the disclosed method may be utilized when forming field effect transistors (FETs) on semiconductor substrates.

As geometries in substrate processing continue to shrink, the technical challenges to forming structures and devices on substrates increase. Field effect transistors, or FETs, are one example of devices that may be formed on a semiconductor substrate using a variety of semiconductor processing techniques. The fabrication of FETs typically involves multiple steps of layer deposition, patterning and etching to define various structures on and/or within a substrate. For example, one type of FET may generally include a source region, a drain region, a channel region positioned between the source region and the drain region, and a gate structure (or simply “gate”) positioned over the channel region. In a planar FET, such as a metal-oxide-semiconductor field effect transistor (MOSFET), the source, drain and channel regions are formed within the substrate, and the gate structure is formed above the substrate over the channel region.

FinFET transistors were developed to improve the operating speed of transistors, while avoiding the deleterious effects often seen when the channel length is reduced in planar MOSFET designs (such as leakage currents that occur in a short channel device when the transistor is switched “off”). Unlike planar MOSFET transistors, FinFET transistors are three-dimensional (3D) transistor designs that use “fins” to form a raised channel between the source and drain regions of the FinFET. In a FinFET design, the gate structure wraps around the raised channel on multiple sides of the fin to form the gate structure. The greater surface area between the gate and the channel reduces leakage currents in the transistor “off” state and enables lower gate voltages to be used to turn the FinFET “on.” Thus, FinFETs typically provide better performance and reduced power consumption compared to planar MOSFET designs. Although FinFETs offer power, performance and scaling benefits, they are not without manufacturing challenges.

FIGS. 1A-B (Prior Art) illustrate one example of a FinFET 10, which is formed on one or more underlying layers, such as an oxide layer 30 and base substrate layer 32. As known in the art, FinFET 10 may generally include one or more fins 12 that extend vertically from the base substrate layer 32, and a gate structure 20 that is oriented orthogonal to the one or more fins 12. Although one fin 12 is shown in FIGS. 1A-1B, it is recognized that FinFET 10 may include a plurality of fins 12, as is known in the art.

Each fin 12 includes a source region 14, a drain region 16 and a channel region 18 positioned between the source region and the drain region. As shown in FIG. 1B, gate structure 20 wraps around the channel region 18 of the fin 12, covering the fin on three sides. As shown in FIG. 1B, a gate oxide layer 22 may be formed between the channel region 18 of the fin 12 and the gate structure 20. In some embodiments, a sidewall spacer layer 24 may be formed adjacent to the gate structure 20 on either side of the gate, as shown in FIG. 1A. In some FinFET designs, epitaxial features 26 may be formed as part of the source region 14 and the drain region 16 to improve the performance of the source/drain regions, as shown in FIG. 2 (Prior Art).

As noted above, FET fabrication methods typically involve multiple steps of layer deposition, patterning and etching to define the various transistor structures formed on and/or within the substrate. In some approaches, a contact etch stop layer (CESL) may be used within a FinFET fabrication process to protect one or more underlying layers, while selectively removing other layers. In some cases, subsequent processing steps may damage or diminish the CESL, resulting in damage to the protected underlying layer(s).

In one example prior art process (not shown), a CESL may be conformally deposited onto the FinFET 10 to protect underlying structures (e.g., the source region 14, drain region 16 and/or epitaxial features 22) during subsequent processing steps. After the CESL is deposited, an oxide layer may be deposited onto the CESL and annealed, before the oxide layer is etched to form contact openings to the source and drain regions. In the prior art process, uncontrolled oxidation of the CESL during the post-oxide anneal step may result in significant loss or thinning of the CESL during a subsequently performed oxide etch step and corresponding damage to underlying source and drain regions. For example, thinning of the CESL may cause the oxide etch to etch through the CESL and damage the source and drain regions and/or thinning of the CESL may result in the CESL removal etch over etching so much that the CESL removal etch damages the source and drain. Further, variations in the etch rate and selectivity of the oxide etch may also cause loss of the CESL and corresponding damage to the underlying source and drain regions. Thus, changes in thickness and/or chemical composition of the CESL caused by the substrate processing may lead to damaging the underlying structures, such as the source region 14, drain region 16 and/or the epitaxial features 22 formed thereon.

A need, therefore, remains for an improved transistor fabrication process that protects a contact etch stop layer (CESL) from oxidation and thinning during subsequent processing steps of the transistor fabrication process.

### SUMMARY

Improved process flows and methods are provided herein for fabricating a transistor, such as a field effect transistor (FET), on a substrate. More specifically, improved process flows and transistor fabrication methods, which utilize a contact etch stop layer (CESL) with improved etch stop capability.

In the disclosed process flows and methods, a CESL is conformally deposited directly onto a plurality of transistor structures, and a sacrificial layer is conformally deposited directly onto the CESL to protect the CESL from oxidation and thinning during subsequent processing step(s). In doing so, the sacrificial layer improves the etch stop capability of the CESL during a subsequently performed oxide etch process. By providing a CESL with improved etch stop capability, the disclosed process flows and methods provide a controlled CESL etch process, which in turn, reduces or avoids damage to underlying transistor structures, such as the source and drain regions and/or the epitaxial features formed as part of those regions.

According to one embodiment, a method for fabricating a transistor in accordance with the techniques described herein may generally include forming a plurality of transistor structures on and/or within the substrate, where the plurality of transistor structures comprise a gate structure, a source region and a drain region. After the transistor structures are formed, the method may include conformally depositing a contact etch stop layer (CESL) directly onto the plurality of transistor structures, and conformally depositing a sacrificial silicon layer directly onto the CESL, such that the sacrificial silicon layer is formed over the plurality of transistor structures. As described in more detail below, the sacrificial silicon layer protects the CESL from oxidation and thinning during subsequent processing step(s), particularly in the regions where contacts to source and drain regions are formed.

In one embodiment, a method for fabricating a transistor on a substrate is provided. The method may comprise forming a plurality of transistor structures on and/or within the substrate, wherein the plurality of transistor structures comprise a gate structure, a source region and a drain region. The method further comprises forming a contact etch stop layer (CESL) on the plurality of transistor structures. The method also comprises forming a sacrificial silicon layer on the CESL such that the sacrificial silicon layer is formed over the plurality of transistor structures, wherein formation of the sacrificial silicon layer includes forming the sacrificial silicon layer on the CESL in the source region where a source contact will be subsequently formed and in the drain region where a drain contact will be subsequently formed. The sacrificial silicon layer protects the CESL formed over the source region and the drain region from oxidation and thinning during subsequent processing steps, thereby preventing damage to the source region and the drain region during the subsequent processing steps.

In embodiments of the methods, the CESL comprises SiN, SiOCN, SiCN, SiBCN, AlN, and/or AlO and the sacrificial silicon layer comprises amorphous silicon or polycrystalline silicon. In some embodiments, forming the CESL comprises conformally depositing the CESL to a thickness ranging between 1 nm and 10 nm and forming the sacrificial silicon layer comprises conformally depositing to a thickness ranging between 1 nm and 5 nm. In some embodiments, the steps of forming the CESL and the forming the sacrificial silicon layer are performed in the same processing chamber using the same deposition process. In one embodiment, the method further comprises forming an oxide layer directly on the sacrificial silicon layer and performing an anneal process, wherein the sacrificial silicon layer protects the CESL from oxidation during said forming the oxide layer and performing the anneal process. In some embodiments, the methods further comprise performing a first etch process to form contact openings above the source region and the drain region, wherein by protecting the CESL from oxidation, the sacrificial silicon layer improves an etch stop capability of the CESL. In still other embodiments, the sacrificial silicon layer is oxidized during said forming the oxide layer and performing the anneal process, and wherein the sacrificial silicon layer is removed during the first etch process. In other embodiments, the methods further comprise, performing a second etch process to remove portions of the CESL overlying the source region and the drain region and to extend the contact openings to the source region and the drain region, wherein by protecting the CESL from thinning, the sacrificial silicon layer reduces or prevents damage to the plurality of transistor structures. In still another embodiment, the transistor is a Fin field effect transistor (FinFET), and the plurality of transistor structures comprise (1) one or more fins that extend vertically from the substrate, wherein the one or more fins comprise a channel region positioned between the source region and the drain region, and (2) the gate structure, wherein the gate structure is oriented orthogonal to the one or more fins.

In yet another embodiment, a method for fabricating a transistor on a substrate is provided. The method may comprises forming a plurality of transistor structures on and/or within the substrate, wherein the plurality of transistor structures comprise (1) one or more fins that extend vertically from the substrate, wherein the one or more fins comprise a source region, a drain region and a channel region positioned between the source region and the drain region, and (2) a gate structure oriented orthogonal to the one or more fins. The method further comprises forming a contact etch stop layer (CESL) on the plurality of transistor structures. The method also comprises forming a sacrificial layer directly on the CESL, such that the sacrificial layer is formed over the plurality of transistor structures, including over the source region and over the drain region. Forming the sacrificial layer protects the CESL in the source region and the drain region from oxidation and thinning during subsequent processing steps.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1A (Prior Art) is a 3D diagram illustrating one example of a FinFET transistor formed on a substrate;

FIG. 1B (Prior Art) is a cross-sectional view through line A-A of FIG. 1A.

FIG. 2 (Prior Art) is a 3D diagram illustrating another example of a FinFET transistor formed on a substrate;

FIGS. 3A-3F illustrate one embodiment of an improved process flow for fabricating a transistor, wherein the process comprises a contact etch stop layer (CESL) with improved etch stop capability.

FIG. 4 is a flowchart diagram illustrating one embodiment of a method for fabricating a transistor in accordance with the techniques described herein.

FIG. 5 is a flowchart diagram illustrating another embodiment of a method for fabricating a transistor in accordance with the techniques described herein.

### DETAILED DESCRIPTION

Improved process flows and methods are provided herein for fabricating a transistor, such as a field effect transistor (FET), on a substrate. More specifically, improved process flows and transistor fabrication methods, which utilize a contact etch stop layer (CESL) with improved etch stop capability.

In the disclosed process flows and methods, a CESL is conformally deposited directly onto a plurality of transistor structures, and a sacrificial layer is conformally deposited directly onto the CESL to protect the CESL from oxidation and thinning during subsequent processing step(s). In doing so, the sacrificial layer improves the etch stop capability of the CESL during a subsequently performed oxide etch process. By providing a CESL with improved etch stop capability, the disclosed process flows and methods provide a controlled CESL etch process, which in turn, reduces or avoids damage to underlying transistor structures, such as the source and drain regions and/or the epitaxial features formed as part of the source and drain regions.

The process flows and methods disclosed herein may utilize a wide variety of CESL materials including, but not limited to, silicon nitride, silicon carbonitride (SiCN), silicon boron carbonitride (SiBCN) or other silicon materials for which good etch selectivity with oxide and source/drain silicon may be obtained. Although CESL materials containing nitride are disclosed herein in exemplary embodiments, the techniques described herein are extendible to other materials commonly used in etch stop layers. Thus, it will be recognized that a nitride CESL is merely exemplary and other CESL layers may be utilized. The process flows and methods disclosed herein may also utilize a wide variety of sacrificial layer materials including, but not limited to, amorphous silicon and polycrystalline silicon (polysilicon). Although sacrificial layer materials containing silicon are disclosed herein as examples, the techniques described herein are extendible to other sacrificial layer materials.

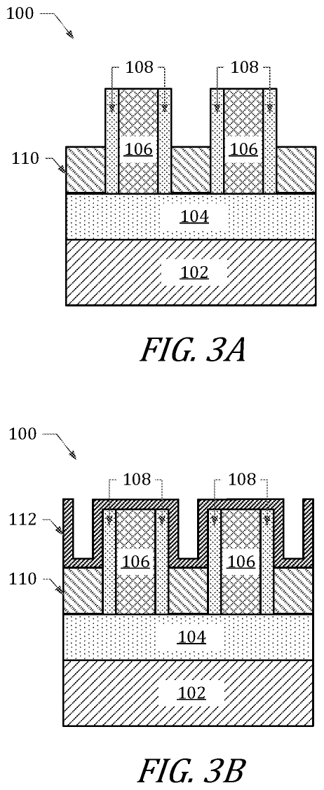

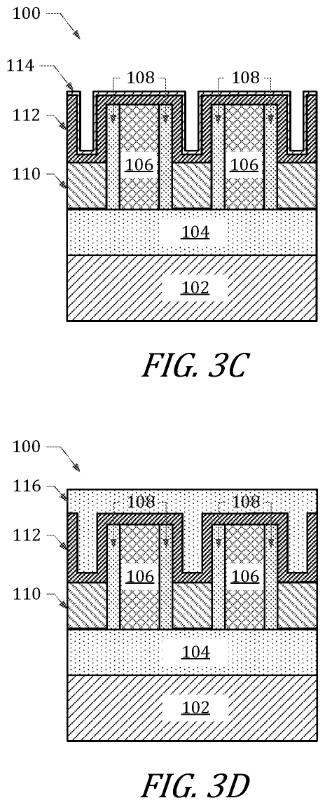

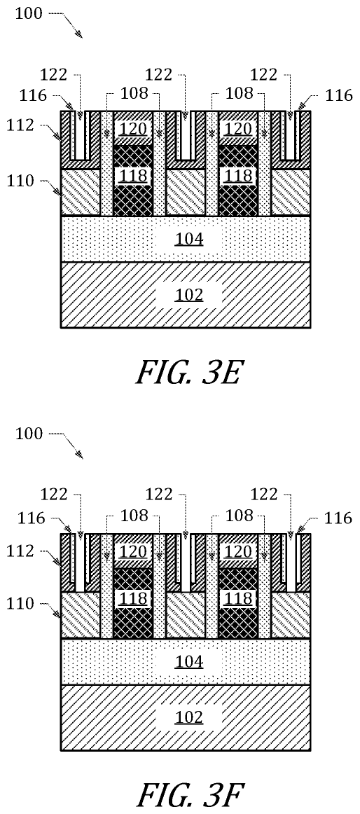

The process flows and methods disclosed herein may generally be used to fabricate a transistor on a substrate, such as a semiconductor substrate. FIGS. 3A-3F illustrate one embodiment of an improved process flow that may be used to form a Fin field effect transistor (FinFET) according to the techniques disclosed herein. It will be recognized that the embodiment shown in FIGS. 3A-3F is merely exemplary and the techniques described herein may be applied to other process flows used to fabricate transistors on a substrate.

The improved process flow shown in FIGS. 3A-3F may generally be used to form one or more FinFETs, each comprising a gate structure and one or more fins, on a substrate. The one or more fins extend vertically from the substrate and include source, drain and channel regions. The gate structure is oriented orthogonal to, and in some embodiments may wrap around, the raised channel region of the one or more fins. In some embodiments, FinFETs formed in accordance with the improved process flow may include epitaxial features formed as part of the source and drain regions of the one or more fins. In other embodiments, epitaxial features may be omitted from the source/drain regions. Although one FinFET embodiment is shown in FIGS. 3A-3F, the techniques described herein may be used to form other types of transistors, such as planar metal-oxide-semiconductor field effect transistors (MOSFETs), on a substrate.

In some embodiments, the techniques described herein may be implemented in conjunction with a “gate last” or replacement metal gate (RMG) transistor fabrication process. A typical RMG process flow includes forming a temporary or sacrificial gate structure, forming additional transistor structures, and then removing the sacrificial gate structure to form a trench. After removing the sacrificial gate structure, various layers of material (e.g., gate dielectric, gate conductor and/or gate cap materials) are deposited within the trench to form a functional gate structure. Thus, the RMG process delays gate formation (i.e., forms the gate last) to avoid damaging gate materials during subsequent processing steps. Although the improved process flow shown in FIGS. 3A-3F is implemented with an RMG process flow, one skilled in the art would recognize that the techniques described herein can alternatively be implemented with other transistor fabrication processes, which do not form the gate last.

FIGS. 3A-3F provide cross-sectional views of a substrate 100 undergoing a transistor fabrication process. In particular, FIGS. 3A-3F illustrate a partial transistor fabrication process flow for fabricating a plurality of FinFETs on the substrate 100. Although two FinFETs are formed on the substrate 100 in the illustrated embodiments, it will be recognized that the techniques shown in FIGS. 3A-3F and described herein may be used to form any number of FinFETs. The cross-sectional views shown in FIGS. 3A-3F assume that additional FinFETs are formed on either side of the FinFETs expressly illustrated in the figures.

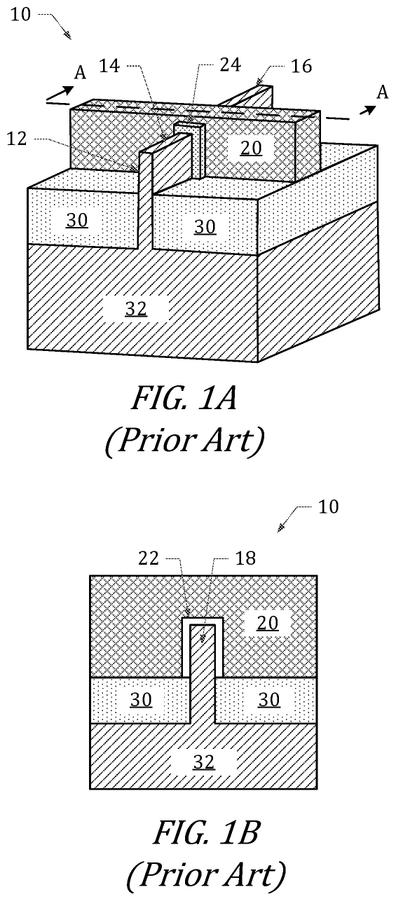

As described in more detail below, each FinFET may generally include a gate structure and one or more fins 110. The cross-sectional views shown in FIGS. 3A-3F are taken through the gate structures of the FinFETs in a plane orthogonal to the gate structures and parallel to one of the one or more fins 110. Although not clearly depicted in the illustrated views, it will be recognized that the one or more fins 110 extend vertically from a base substrate 102 layer of the substrate 100, similar to that shown and described in FIG. 1A. Although not labeled in the figures, it will also be recognized that each of the raised fins 110 includes source, drain and channel regions, as shown in FIGS. 1A and 1B. It will be further recognized that each gate structure may be oriented orthogonal to the raised channel region of the one or more fins 110.

In the embodiment shown in FIG. 3A, FinFET structures have been formed on and/or within one or more underlying layers of substrate 100. The FinFET structures shown in FIG. 3A include sacrificial gate structures 106, sidewall spacers 108 and the one or more fins 110. The underlying layers shown in FIG. 3A include, but are not limited to, an oxide layer 104 and a base substrate 102. It is recognized that the underlying layers described and shown in the figures are merely exemplary, and more, less or other underlying layers may be utilized.

Base substrate 102 may be any substrate for which the use of patterned features is desirable. For example, base substrate 102 may be a semiconductor substrate having one or more semiconductor processing layers formed thereon. In one embodiment, base substrate 102 may be a substrate that has been subject to multiple semiconductor processing steps which yield a wide variety of structures and layers, all of which are known in the substrate processing art. Non-limiting examples of suitable materials for base substrate 102 include Si (silicon), strained Si, SiC (silicon carbide), Ge (germanium), SiGe (silicon germanium), SiGeC (silicon-germanium-carbon), Si alloys, Ge alloys, III-V materials (e.g., GaAs (gallium arsenide), InAs (indium arsenide), InP (indium phosphide), or aluminum arsenide (AlAs)), II-VI materials (e.g., CdSe (cadmium selenide), CdS (cadmium sulfide), CdTe (cadmium telluride), ZnO (zinc oxide), ZnSe (zinc selenide), ZnS (zinc sulfide), or ZnTe (zinc telluride)), or any combination thereof.

Similar to the one or more fins 12 shown in FIG. 1A, the one or more fins 110 shown in FIGS. 3A-3F rise or extend vertically from base substrate 102 through oxide layer 104. The oxide layer 104 may be formed from any of a wide variety of oxide dielectric materials, as is known in the art. Other dielectrics may also be utilized.

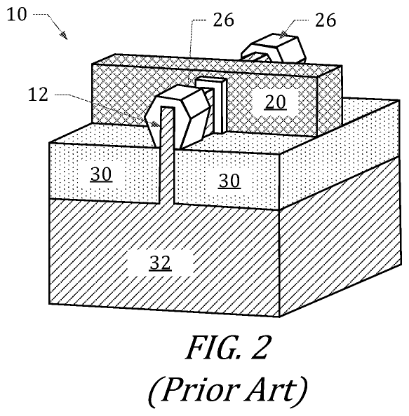

Although not labeled in the figures, each fin 110 includes a source region, a drain region and a channel region positioned between the source region and the drain region. The one or more fins 110 may be formed from any of a wide variety of electrically conductive materials, as is known in the art. In one embodiment, the one or more fins 110 may be formed from a silicon material, though it will be recognized that the fins may be formed of materials similar to the wide variety of base substrate materials described above. In some embodiments, epitaxial features (not shown) may be formed as part of the source and drain regions of the one or more fins 110, similar to the epitaxial features 26 shown in FIG. 2. In one embodiment, epitaxial features may be formed from of epitaxial silicon, though again it will be recognized that other materials may be utilized.

In the embodiment shown in FIG. 3A, sacrificial gate structures 106 are formed on the oxide layer 104, and sidewall spacers 108 are formed adjacent to the sacrificial gate structures 106 on each side of the gate structures. The sacrificial gate structures 106 may wrap around the channel region (not shown) of the one or more fins 110, covering the fin(s) on three sides, similar to the structure 20 shown in FIG. 1A. Similar to the gate oxide layer 22 shown in FIG. 1B, a gate oxide layer may also be formed between the channel region of the fin(s) 110 and the sacrificial gate structures 106.

The sacrificial gate structures 106 may be formed from a wide variety of materials, as is known in the art. In one embodiment, the sacrificial gate structures 106 may be formed from polysilicon. However, other materials may also be used to implement the sacrificial gate structures 106 as is known in the art. The sacrificial gate structures 106 shown in FIG. 3A provide a temporary gate structure, which may be subsequently removed and replaced with a functional gate structure, as shown in FIG. 3E and described in more detail below.

Sidewall spacers 108 are formed adjacent to the sacrificial gate structures 106 on either side of the gate structures, as is known in the art. The sidewall spacers 108 may be formed from a wide variety of dielectric materials, as is known in the art. In some embodiments, the sidewall spacers 108 may be formed from a low-k dielectric material. Other dielectric materials may also be used to implement the sidewall spacers 108, as is known in the art.

After the FinFET structures shown in FIG. 3A are formed, a contact etch stop layer (CESL) 112 is formed on the FinFET structures, as shown in FIG. 3B. In one embodiment, a deposition process may be performed to conformally deposit the CESL 112 onto the sacrificial gate structures 106, the sidewall spacers 108, and the one or more fins 110 (including the source and drain regions formed therein). Although not shown in FIG. 3A, the CESL 112 is also directly deposited onto portions of the oxide layer 104 located between the one or more fins 110. The CESL 112 may generally be used to protect the underlying FinFET structures during one or more subsequent processing steps. For example, the CESL 112 may protect underlying FinFET structures (such as, e.g., the source regions, drain regions and any epitaxial formed as part of the source and drain regions) by providing an etch stop during a subsequently performed oxide etch step, as shown in FIG. 3E and described in more detail below.

After the CESL 112 is deposited, a sacrificial silicon layer 114 is deposited onto the CESL 112, as shown in FIG. 3C. More specifically, a deposition process is performed to conformally deposit the sacrificial silicon layer 114 onto the CESL 112. In doing so, the sacrificial silicon layer 114 may be formed directly above the sacrificial gate structures 106, the sidewall spacers 108, the one or more fins 110 (including the source and drain regions formed therein), and the portions of the oxide layer 104 located between the one or more fins 110. The sacrificial silicon layer 114 may generally be used to protect the CESL 112 during one or more subsequent processing steps. For example, the sacrificial silicon layer 114 may protect the CESL 112 from oxidation during a subsequently performed oxide deposition and anneal step, as shown in FIG. 3D and described in more detail below. Though described herein in one exemplary embodiment as a sacrificial silicon layer 114, the sacrificial layer may be formed of other materials as described below.

The CESL 112 and sacrificial layer formed on the CESL 112 may each be formed from a wide variety of materials. In some embodiments, the CESL 112 may be formed from a etch stop material, such as silicon nitride (SiN), silicon oxynitride (SiON), silicon carbide (SiC), silicon carbonitride (SiCN), silicon oxycarbonitride (SiOCN), silicon boron carbonitride (SiBCN), silicon carbon oxide (SiOC), hydrogen doped silicon nitride carbide (SiNCH), aluminum oxide (AlO), aluminum nitride (AlN), and/or other dielectric materials or combinations of materials that show good etch selectivity to the overlying oxide and the underlying source/drain silicon. Other etch stop materials may also be used to implement the CESL 112, as is known in the art. To protect the CESL 112 from oxidation and potential overetch, the sacrificial layer may be formed from a silicon-containing material such as for example silicon (for example as shown with sacrificial silicon layer 114) or other silicon materials that easily oxidizes. In some embodiments, the sacrificial silicon layer 114 may comprise amorphous silicon or polysilicon. Further, the sacrificial silicon layer 114 need not be comprised of only silicon, but rather may merely be a silicon containing material. As mentioned, other oxidizable materials may also be used to implement the sacrificial layer.

A variety of deposition processes may be used to conformally deposit the CESL 112 and the sacrificial silicon layer 114. For example, the CESL 112 and the sacrificial silicon layer 114 may be deposited using chemical vapor deposition (CVD), plasma enhanced CVD (PECVD), physical vapor deposition (PVD), atomic layer deposition (ALD), and/or other deposition processes. In some embodiments, the CESL 112 and the sacrificial silicon layer 114 may be deposited in the same processing chamber using the same deposition process (e.g., CVD). In other embodiments, different deposition processes may be used to deposit the CESL 112 and the sacrificial silicon layer 114.

In one preferred embodiment, a silicon nitride CESL 112 may be deposited onto the FinFET structures shown in FIGS. 3A and 3B through a CVD process performed within a processing chamber. For example, a plasma enhanced CVD process at low pressures of 400 to 800 mT and a temperature of 500-650 degrees C. may be utilized. Other deposition methods such as, but not limited to, high density plasma (HDP) CVD, sub-atmospheric CVD (SACVD), molecular layer deposition (MLD) may also be used. In one embodiment, the silicon nitride CESL 112 may be deposited to a thickness ranging between 2 nm and 10 nm. After the silicon nitride CESL 112 is deposited, a relatively thin (e.g., 2 nm-5 nm) sacrificial silicon layer 114 of amorphous silicon may be conformally deposited onto the silicon nitride CESL 112 through another CVD process performed within the same processing chamber. For example, a CVD process at low pressures of 100 to 400 mT and a temperature of 580-650 degrees C. may be utilized.

After the sacrificial silicon layer 114 is deposited, a flowable oxide layer 116 is deposited onto the sacrificial silicon layer 114 to fill in the gaps between the sacrificial gate structures 106 (and sidewall spacers 108), as shown in FIG. 3D. In some embodiments, the flowable oxide layer 116 may be formed from a silicon precursor material, such as alkoxysilanes, tetraethoxysilane (TEOS), or trimethoxysilane (TriMOS). Other oxide materials may also be used to implement the flowable oxide layer 116, as is known in the art.

A variety of deposition processes may be used to deposit the flowable oxide layer 116 onto the sacrificial silicon layer 114. For example, a plasma assisted CVD process at low temperature (30 to 100 degrees C.) and a pressure of 0.1 to 1 Torr may be used to deposit the flowable oxide. In some embodiments, the flowable oxide layer 116 may be deposited to a thickness ranging between 50 nm and 200 nm. After the flowable oxide layer 116 is deposited, an anneal process may be used to increase the density of at least a portion of the flowable oxide layer 116. Suitable anneal processes include, but are not limited to, those involving exposure to a steam, thermal, ultraviolet (UV), electron-beam (e-beam), microwave, laser or plasma source in an oxidative or inert environment.

In the improved process flows and methods disclosed herein, sacrificial silicon layer 114 functions as a protective layer, which protects the CESL 112 from oxidation during the oxide deposition and anneal step shown in FIG. 3D. As described in more detail below, the sacrificial silicon layer 114 also functions as a sacrificial layer, which may be in part or fully oxidized during the post-oxide anneal step of FIG. 3D and subsequently removed during the oxide etch step shown in FIG. 3E. Because the sacrificial silicon layer 114 may be oxidized completely during the oxide deposition and anneal step, it is not shown in FIG. 3D.

Various processes may be performed after the oxide deposition and anneal step shown in FIG. 3D, such as for example a chemical mechanical planarization process, a contact etch process and a gate replacement process. FIG. 3E illustrates the substrate 100 after these processes. For example, A CMP step (to planarize the deposited oxide) and then an oxide etch process may be performed to remove a majority of the flowable oxide layer 116 from the substrate 100 and form contact openings 122 above the source and drain regions of the one or more fins 110, as shown in FIG. 3E. Because CESL 112 functions as an etch stop layer during the oxide etch process, the oxide etch process shown in FIG. 3E is configured to be highly selective to the etch stop material used to form the CESL 112. In addition, a gate replacement process may also be performed as described in more detail below.

For example, the CESL 112 is preferably formed from a material having a much slower etch rate than the material used for the flowable oxide layer 116. Regardless of the particular material chosen, CESL 112 preferably exhibits different etch characteristics (e.g., etch rate, etch selectivity, etc.) than the flowable oxide layer 116. These different etch characteristics allow the CESL 112 to act as an etch stop during the oxide etch process shown in FIG. 3E, and to protect underlying FinFET structures. In one example embodiment, the oxide etch process may utilize a C₄F₆/argon/oxygen based plasma chemistry at low pressures of 10 to 100 mT.

In some embodiments, a replacement metal gate (RMG) process may be performed to remove the sacrificial gate structures 106 and replace them with functional gate structures, as shown in FIG. 3E. The RMG process may generally include at least one etch process and at least one deposition process. For example, the RMG process may use an etch process to remove the sacrificial gate structures 106, while leaving the sidewall spacers 108 intact.

After removing the sacrificial gate structures 106, the RMG process may utilize one or more deposition processes to deposit various materials within the trenches formed between each pair of the sidewall spacers 108. In some embodiments, a metal gate 118 and a gate cap 120 may be formed between each pair of sidewall spacers 108, as shown in FIG. 3E. The metal gate 118 and gate cap 120 may each be formed from a wide variety of materials and methods, as is known in the art.

After performing the oxide etch and RMG process shown in FIG. 3E, an additional etch process may be performed to extend the contact openings 122 to the source and drain regions of the one or more fins 110 by removing portions of the CESL 112 overlying the source and drain regions. In one example embodiment, the etch process used to remove the CESL 112 overlying the source/drain regions and form contact openings 122 may use CHF₃/argon/oxygen based plasma chemistry at low pressures of 10 to 100 mT.

As noted above, prior art processes for fabricating FinFET transistors use contact etch stop layers to protect underlying FinFET structures during subsequent processing steps. In the prior art process discussed in the background section, a CESL is deposited onto the FinFET structures and an oxide layer (such as flowable oxide layer 116 of FIG. 3D) is deposited onto the CESL and annealed. During the post-oxide anneal, at least a portion of the CESL used in the prior art process is oxidized, resulting in significant loss and thinning of the CESL. Such thinning may lead to damage to the source/drain regions and/or the epitaxial features formed as part of the source/drain regions as described above in the background.

The improved process flow shown in FIGS. 3A-3F improves upon prior art transistor fabrication processes, at least in one respect, by forming a thin, sacrificial silicon layer 114 over the CESL 112. As noted above, the sacrificial silicon layer 114 is conformally deposited onto the CESL 112 and formed above the sacrificial gate structures 106, sidewall spacers 108, and one or more fins 110, as well as portions of the oxide layer 104 located between the one or more fins 110. The sacrificial silicon layer 114 functions as: (a) a protective layer, which protects the CESL 112 from oxidation during the post oxide anneal step shown in FIG. 3D; and (b) a sacrificial layer, which is partially or fully oxidized during the post oxide anneal step shown in FIG. 3D and removed during the oxide etch step shown in FIG. 3E.

By protecting the CESL 112 from oxidation, sacrificial silicon layer 114 improves the etch stop capability of the CESL 112 during the oxide etch step shown in FIG. 3E. As a consequence, the improved process flow shown in FIGS. 3A-3F provides more tolerance and process margin with higher selectivity to the CESL 112 during the oxide etch step than is typically provided in prior art processes. By avoiding oxidation and thinning of the CESL 112, the improved process flow shown in FIGS. 3A-3F provides a more controlled CESL etch process (FIG. 3F), which in turn, reduces or prevents damage to underlying transistor structures, such as the source/drain regions and/or the epitaxial features formed thereon.

In some embodiments, forming a sacrificial silicon layer 114 on the CESL 112, as described herein, may also enable a thinner (e.g., 1 nm to 5 nm) CESL 112 to be used, compared to contact etch stop layers (e.g., 2 nm to 10 nm) typically used in prior art processes. Also, reducing the thickness of the CESL 112 on the gate sidewall (e.g., on sidewall surfaces of the sidewall spacers 108) reduces gate capacitance and improves the operational speed of the FinFET transistor.

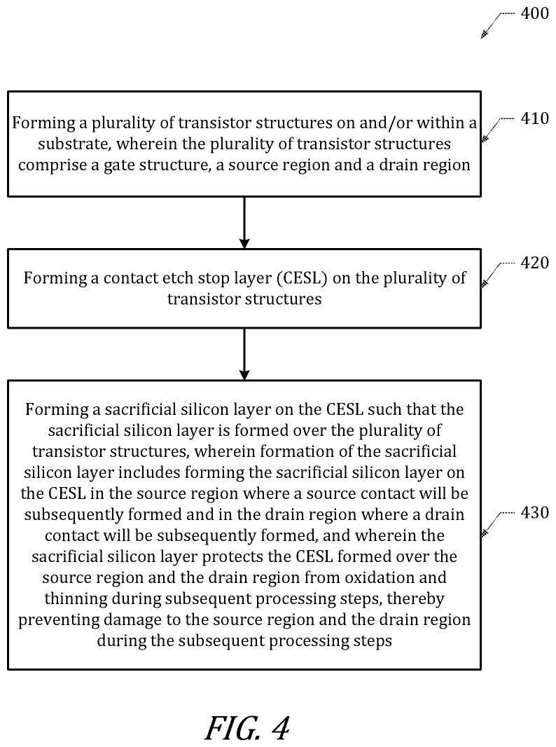

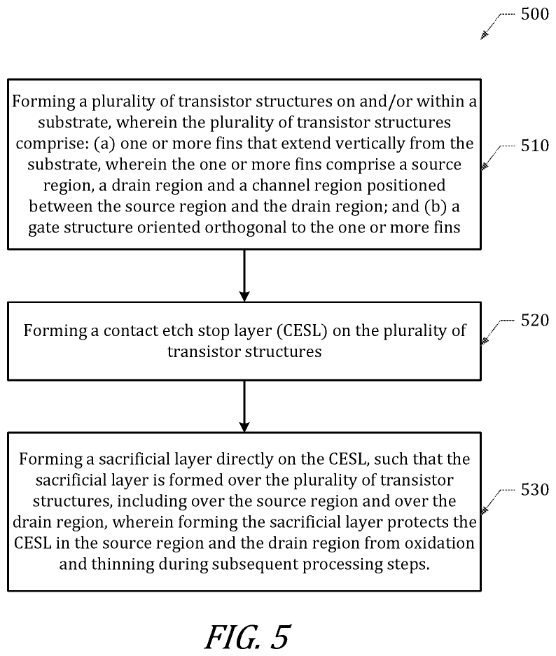

FIGS. 4-5 illustrate exemplary methods for fabricating a transistor that use the techniques described herein. It will be recognized that the embodiments of FIGS. 4-5 are merely exemplary and additional methods may utilize the techniques described herein. Further, additional processing steps may be added to the methods shown in the FIGS. 4-5 as the steps described are not intended to be exclusive. Moreover, the order of the steps is not limited to the order shown in the figures as different orders may occur and/or various steps may be performed in combination or at the same time.

FIG. 4 illustrates one embodiment of a method 400 that may be used to fabricate a transistor on a substrate using the techniques disclosed herein. In some embodiments, method 400 may begin by forming a plurality of transistor structures on and/or within the substrate, wherein the plurality of transistor structures comprise a gate structure, a source region and a drain region (in step 410).

Next, method 400 includes forming a contact etch stop layer (CESL) on the plurality of transistor structures (in step 420), and forming a sacrificial silicon layer on the CESL, such that the sacrificial silicon layer is formed over the plurality of transistor structures (in step 430). In this embodiment, the step of forming the sacrificial silicon layer includes forming the sacrificial silicon layer on the CESL in the source region where a source contact will be subsequently formed and in the drain region where a drain contact will be subsequently formed. In doing so, the sacrificial silicon layer protects the CESL formed over the source region and the drain region from oxidation and thinning during subsequent processing steps, thereby preventing damage to the source region and the drain region during the subsequent processing steps.

FIG. 5 illustrates another embodiment of a method 500 that may be used to fabricate a transistor on a substrate using the techniques disclosed herein. In some embodiments, method 500 may begin by forming a plurality of transistor structures on and/or within the substrate (in step 510). In this embodiment, the plurality of transistor structures may generally include one or more fins and a gate structure oriented orthogonal to the one or more fins. The one or more fins extend vertically from the substrate, and include a source region, a drain region and a channel region positioned between the source region and the drain region.

Next, method 500 includes forming a contact etch stop layer (CESL) on the plurality of transistor structures (in step 520), and forming a sacrificial layer directly on the CESL, such that the sacrificial layer is formed over the plurality of transistor structures, including over the source region and over the drain region (in step 530). In this embodiment, the sacrificial layer protects the CESL in the source region and the drain region from oxidation and thinning during subsequent processing steps.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

Process flows and methods for processing a substrate are described herein in various embodiments. The substrate may include any material portion or structure of a device, particularly a semiconductor or other electronics device, and may, for example, be a base substrate structure, such as a semiconductor substrate or a layer on or overlying a base substrate structure such as a thin film. Thus, substrate is not intended to be limited to any particular base structure, underlying layer or overlying layer, patterned or unpatterned layer, but rather, is contemplated to include any such layer or base structure, and any combination of layers and/or base structures.

It is noted that various deposition processes can be used to form one or more of the material layers shown and described herein. For example, one or more depositions can be implemented using chemical vapor deposition (CVD), plasma enhanced CVD (PECVD), physical vapor deposition (PVD), atomic layer deposition (ALD), and/or other deposition processes. It is further noted that various etch processes can be used to etch one or more of the material layers shown and described herein. For example, one or more etch processes can be implemented using plasma etch processes, discharge etch processes, and/or other desired dry or wet etch processes.

Other operating variables for process steps can also be adjusted to control the various deposition and/or etch processes described herein. The operating variables may include, for example, the chamber temperature, chamber pressure, flowrates of gases, types of gases, and/or other operating variables for the processing steps. Variations can also be implemented while still taking advantage of the techniques described herein.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the described systems and methods will be apparent to those skilled in the art in view of this description. It will be recognized, therefore, that the described systems and methods are not limited by these example arrangements. It is to be understood that the forms of the systems and methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for fabricating a transistor on a substrate, the method comprising:
forming a plurality of transistor structures on and/or within the substrate, wherein the plurality of transistor structures comprise a gate structure, a source region and a drain region;
forming a contact etch stop layer (CESL) on the plurality of transistor structures; and
forming a sacrificial silicon layer on the CESL such that the sacrificial silicon layer is formed over the plurality of transistor structures, wherein formation of the sacrificial silicon layer includes forming the sacrificial silicon layer on the CESL in the source region where a source contact will be subsequently formed and in the drain region where a drain contact will be subsequently formed;
wherein the sacrificial silicon layer protects the CESL formed over the source region and the drain region from oxidation and thinning during subsequent processing steps, thereby preventing damage to the source region and the drain region during the subsequent processing steps.

2. The method of claim 1, wherein the CESL comprises SiN, SiOCN, SiCN, SiBCN, AlN, and/or AlO.

3. The method of claim 1, wherein the sacrificial silicon layer comprises amorphous silicon or polycrystalline silicon.

4. The method of claim 1, wherein the forming the CESL comprises conformally depositing the CESL to a thickness ranging between 1 nm and 10 nm.

5. The method of claim 1, wherein the forming the sacrificial silicon layer comprises conformally depositing to a thickness ranging between 1 nm and 5 nm.

6. The method of claim 1, wherein the steps of forming the CESL and the forming the sacrificial silicon layer are performed in the same processing chamber using the same deposition process.

7. The method of claim 1, further comprising:
forming an oxide layer directly on the sacrificial silicon layer and performing an anneal process; and
wherein the sacrificial silicon layer protects the CESL from oxidation during said forming the oxide layer and performing the anneal process.

8. The method of claim 7, further comprising:
performing a first etch process to form contact openings above the source region and the drain region; and
wherein by protecting the CESL from oxidation, the sacrificial silicon layer improves an etch stop capability of the CESL.

9. The method of claim 8, wherein the sacrificial silicon layer is oxidized during said forming the oxide layer and performing the anneal process, and wherein the sacrificial silicon layer is removed during the first etch process.

10. The method of claim 8, further comprising:
performing a second etch process to remove portions of the CESL overlying the source region and the drain region and to extend the contact openings to the source region and the drain region; and
wherein by protecting the CESL from thinning, the sacrificial silicon layer reduces or prevents damage to the plurality of transistor structures.

11. The method of claim 1, wherein the transistor is a Fin field effect transistor (FinFET), and wherein the plurality of transistor structures comprise:
one or more fins that extend vertically from the substrate, wherein the one or more fins comprise a channel region positioned between the source region and the drain region; and
the gate structure, wherein the gate structure is oriented orthogonal to the one or more fins.

12. A method for fabricating a transistor on a substrate, the method comprising:
forming a plurality of transistor structures on and/or within the substrate, wherein the plurality of transistor structures comprise:
one or more fins that extend vertically from the substrate, wherein the one or more fins comprise a source region, a drain region and a channel region positioned between the source region and the drain region; and
a gate structure oriented orthogonal to the one or more fins;
forming a contact etch stop layer (CESL) on the plurality of transistor structures; and
forming a sacrificial layer directly on the CESL, such that the sacrificial layer is formed over the plurality of transistor structures, including over the source region and over the drain region;
wherein forming the sacrificial layer protects the CESL in the source region and the drain region from oxidation and thinning during subsequent processing steps.

13. The method of claim 12, wherein the CESL comprises SiN, SiOCN, SiCN, SiBCN, AlN, and/or AlO.

14. The method of claim 12, wherein the sacrificial layer comprises amorphous silicon or polycrystalline silicon.

15. The method of claim 12, wherein the forming the CESL comprises conformally depositing the CESL to a thickness ranging between 1 nm and 10 nm.

16. The method of claim 12, wherein the forming the sacrificial layer comprises conformally depositing the sacrificial layer to a thickness ranging between 1 nm and 5 nm.

17. The method of claim 12, further comprising:
forming an oxide layer directly on the sacrificial layer; and
performing a post-oxide anneal process after the oxide layer is formed;
wherein the sacrificial layer protects the CESL from oxidation during said post-oxide anneal process.

18. The method of claim 17, further comprising:
performing a first etch process to remove the oxide layer and form contact openings above the source region and the drain region; and
wherein by protecting the CESL from oxidation, the sacrificial layer improves an etch stop capability of the CESL.

19. The method of claim 18, wherein the sacrificial silicon layer is oxidized during said post-oxide anneal process.

20. The method of claim 18, further comprising:
performing a second etch process to remove portions of the CESL overlying the source region and the drain region and to extend the contact openings to the source region and the drain region; and
wherein by protecting the CESL from thinning, the sacrificial layer reduces or prevents damage to the source region and the drain region.
